(19) United States
(12) Patent Application Publication
(10) Pub. No.: US 2026/0269831 A1
(43) Pub. Date: Sep. 10, 2026

(54) BUFFER OUTPUT DEVICE HAVING FEEDTHROUGH CANCELLATION MECHANISM AND BUFFER OUTPUT METHOD THEREOF

(71) Applicant: REALTEK SEMICONDUCTOR CORPORATION, Hsinchu (TW)

(72) Inventor: Shih-Hsiung HUANG, Hsinchu (TW)

(21) Appl. No.: 19/541,444

(22) Filed: Feb. 17, 2026

(30) Foreign Application Priority Data
Mar. 6, 2025 (TW) 114108414

(51) Int. Cl. H03K 19/0185; H03K 17/16

(52) U.S. Cl. CPC H03K 19/018521; H03K 17/162

(57) ABSTRACT

A buffer output device includes a buffer circuit, first switches, and a feedthrough cancellation circuit. The first switches are configured to be turned on according to a first clock signal to provide a first input signal to a first input node of the buffer circuit and to provide a second input signal to a second input node of the buffer circuit, in which the buffer circuit is configured to generate a first output signal from a first output node according to the first input signal and to generate a second output signal from a second output node according to the second input signal. The feedthrough cancellation circuit is turned on according to a second clock signal when the first switches are turned off, to couple the second output node to the first input node and to couple the first output node to the second input node.

### BACKGROUND OF THE INVENTION

### 1. Field of the Invention

The present disclosure relates to a buffer output device, and more particularly to a buffer output device having a feedthrough cancellation mechanism and a buffer output method thereof.

### 2. Description of Related Art

In a sampling circuit, when a sampling switch is turned off, an input signal may still be erroneously transmitted to an output node through the sampling switch and parasitic elements in a subsequent stage circuit, thereby affecting a signal level on the output node. As a result, signal accuracy on the output node is reduced and the accuracy of subsequent signal processing is decreased.

### SUMMARY OF THE INVENTION

In some aspects, one of the objects of the present disclosure is (but is not limited to) providing a buffer output device having a feedthrough cancellation mechanism and a buffer output method thereof, so as to make an improvement to the prior art.

In some aspects, a buffer output device includes a buffer circuit, a plurality of first switches, and a feedthrough cancellation circuit. The plurality of first switches are configured to be turned on according to a first clock signal to provide a first input signal to a first input node of the buffer circuit and to provide a second input signal to a second input node of the buffer circuit, in which the buffer circuit is configured to generate a first output signal from a first output node according to the first input signal and to generate a second output signal from a second output node according to the second input signal. The feedthrough cancellation circuit is configured to be turned on according to a second clock signal when the plurality of first switches are turned off, to couple the second output node to the first input node and to couple the first output node to the second input node.

In some aspects, a buffer output method includes the following operations: turning on a plurality of first switches according to a first clock signal, to provide a first input signal to a first input node of a buffer circuit and to provide a second input signal to a second input node of the buffer circuit; generating, by the buffer circuit, a first output signal from a first output node and a second output node from a second output node according to the first input signal and the second input signal; and turning on a feedthrough cancellation circuit according to a second clock signal when the plurality of first switches are turned off, in order to couple, via the feedthrough cancellation circuit, the second output node to the first input node and to couple the first output node to the second input node.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 is a schematic diagram of a buffer output device according to some embodiments of the present disclosure.

FIG. 2 is a schematic diagram of a buffer output device according to some embodiments of the present disclosure.

FIG. 3 is a schematic diagram of waveforms of the clock signals in FIGS. 1 or 2 according to some embodiments of the present disclosure.

FIG. 4 is a schematic diagram of the buffer circuit in FIGS. 1 or 2 according to some embodiments of the present disclosure.

FIG. 5 is a flow chart of a buffer output method according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuit” may indicate an object, which is formed with one or more transistors and/or one or more active/passive elements according to a specific arrangement, for processing signals.

As used herein, the term "and/or" includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, similar/identical elements in various figures are designated with the same reference number.

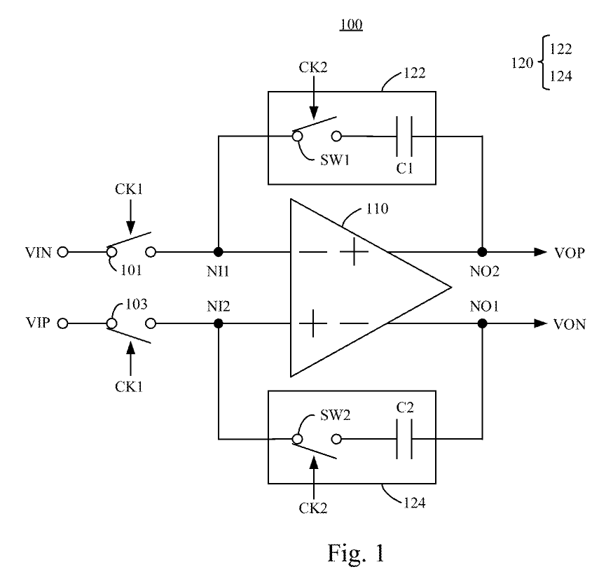

FIG. 1 is a schematic diagram of a buffer output device 100 according to some embodiments of the present disclosure. In some embodiments, the buffer output device 100 may be applied to a sampling circuit, but the present disclosure is not limited thereto. The buffer output device 100 includes a switch 101, a switch 103, a buffer circuit 110, and a feedthrough cancellation circuit 120.

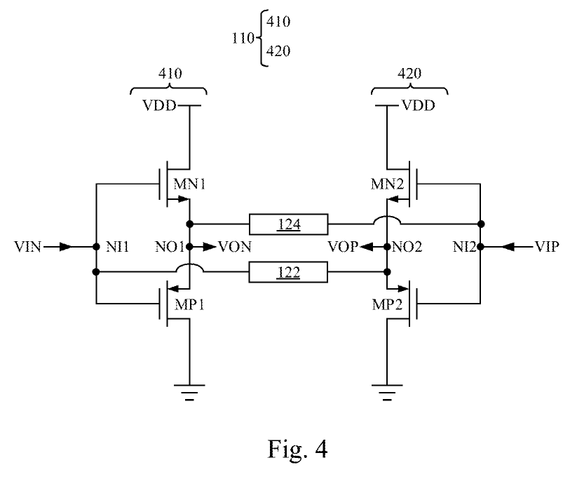

The switch 101 and the switch 103 are turned on according to a clock signal CK1, in order to provide an input signal VIN to an input node NI1 of the buffer circuit 110 (for example, which may correspond to a negative input terminal) and provide an input signal VIP to an input node NI2 of the buffer circuit 110 (for example, which may correspond to a positive input terminal). The buffer circuit 110 is configured to generate an output signal VON from an output node NO1 (for example, which may correspond to a negative output terminal) according to the input signal VIN, and to generate an output signal VOP from an output node NO2 (for example, which may correspond to a positive output terminal) according to the input signal VIP. In some embodiments, the buffer circuit 110 may be an analog buffer circuit. For example, the buffer circuit 110 may be implemented with, but is not limited to, several source followers. Related arrangements will be described later with reference to FIG. 4.

The feedthrough cancellation circuit 120 is configured to be turned on according to a clock signal CK2 when the switch 101 and the switch 103 are turned off, in order to couple the output node NO2 to the input node NI1 and to couple the output node NO1 to the input node NI2. On the other hand, the feedthrough cancellation circuit 120 is further configured to be turned off according to the clock signal CK2 when the switch 101 and the switch 103 are turned on, in order to disconnect the output node NO2 from the input node NI1 and to disconnect the output node NO1 from the input node NI2. In other words, when the switch 101 and the switch 103 are turned on according to a clock signal CK1 to provide the input signal VIN and the input signal VIP to the buffer circuit 110, the feedthrough cancellation circuit 120 is turned off according to the clock signal CK2, in order to avoid affecting the operation of the buffer circuit 110. When the switch 101 and the switch 103 are turned off according to the clock signal CK1, the feedthrough cancellation circuit 120 is turned on according to the clock signal CK2 to perform feedthrough cancellation (that is, to couple the output node NO2 to the input node NI1 and to couple the output node NO1 to the input node NI2).

In greater detail, the feedthrough cancellation circuit 120 may include a path 122 and a path 124. The path 122 is coupled between the output node NO2 and the input node NI1, and the path 124 is coupled between the output node NO1 and the input node NI2. In some embodiments, the path 122 and the path 124 may have the same circuit structure. Taking the path 122 as an example, the path 122 includes a switch SW1 and a capacitor C1. The capacitor C1 is coupled to the output node NO2, and the switch SW1 is coupled between the input node NI1 and the capacitor C1. The switch SW1 is configured to be turned on according to a clock signal CK2, to couple the input node NI1 to the output node NO2 via the capacitor C1. Similarly, the path 124 includes a switch SW2 and a capacitor C2. The capacitor C2 is coupled to the output node NO1, and the switch SW2 is coupled between the input node NI2 and the capacitor C2. The switch SW2 is configured to be turned on according to the clock signal CK2, to couple the input node NI2 to the output node NO1 via the capacitor C2.

In some embodiments, the input signal VIN and the input signal VIP may be differential signals. Ideally, when the switch 101 and the switch 103 are turned off, the input signal VIN and the input signal VIP are not provided to the input node NI1 and the input node NI2 of the buffer circuit 110. However, in practical applications, as there are parasitic elements in the switch 101, the switch 103, and internal transistors in the buffer circuit 110, during the period when the switch 101 and the switch 103 are turned off, the input signal VIN and the input signal VIP may still feed through (i.e., coupled) to the output node NO1 and the output node NO2 via the switch 101, the switch 103, and the aforementioned parasitic elements of the internal transistors, thereby reducing the output accuracy of the buffer circuit 110. To improve the above problem, the feedthrough cancellation circuit 120 may couple the input node NI1 to the output node NO2 and couple the input node NI2 to the output node NO1 during the period when the switch 101 and the switch 103 are turned off, thereby using the characteristics of differential signals to reduce the influence of the aforementioned signal feedthrough.

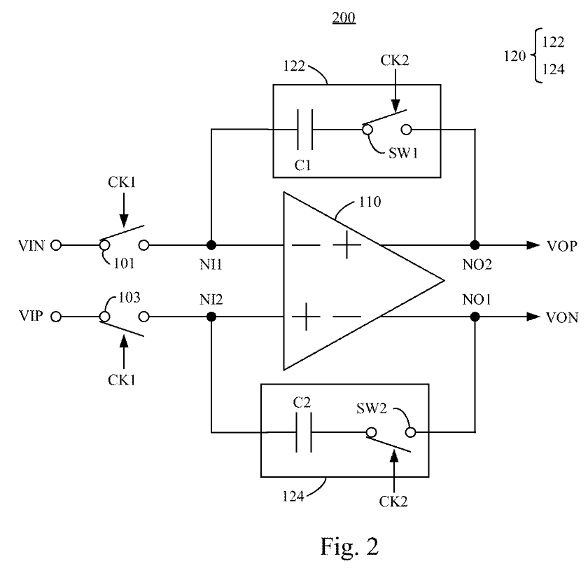

FIG. 2 is a schematic diagram of a buffer output device 200 according to some embodiments of the present disclosure. Different from the buffer output device 100 in FIG. 1, in this example, the capacitor C1 is coupled to the input node NI1, and the switch SW1 is coupled between the output node NO2 and the capacitor C1 and is configured to be turned on according to a clock signal CK2 to couple the output node NO2 to the input node NI1 via the capacitor C1. Similarly, the capacitor C2 is coupled to the input node NI2, and the switch SW2 is coupled between the output node NO1 and the capacitor C2 and is configured to be turned on according to the clock signal CK2 to couple the output node NO1 to the input node NI2 via the capacitor C2.

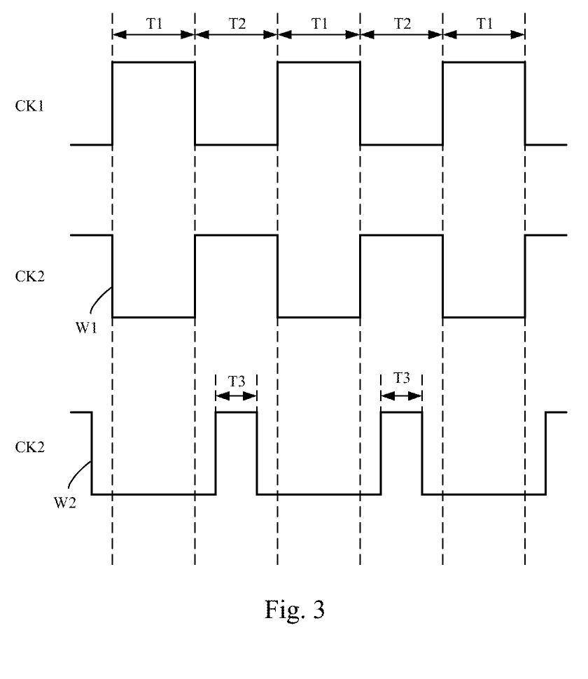

FIG. 3 is a schematic diagram of waveforms of the clock signal CK1 and the clock signal CK2 in FIGS. 1 or 2 according to some embodiments of the present disclosure. As shown in FIG. 3, the switch 101 and the switch 103 may be turned on during a period T1 in which the clock signal CK1 has a high level and may not be turned on during a period T2 in which the clock signal CK1 has a low level. Correspondingly, the switch SW1 and the switch SW2 may be configured to be turned on during the aforementioned period T2. In some embodiments, as shown by waveform W1, the clock signal CK2 and the clock signal CK1 may have opposite phases. That is, when the clock signal CK1 has a high level, the clock signal CK2 has a low level; and vice versa. In other embodiments, as shown by waveform W2, the clock signal CK1 and the clock signal CK2 may be set to be non-overlapping clock signals, that is, there is a time difference between a falling edge of the clock signal CK1 and a rising edge of the clock signal CK2, and there is the same time difference between a rising edge of the clock signal CK1 and a falling edge of the clock signal CK2. With the above waveform arrangements, a period in which the feedthrough cancellation circuit 120 is turned on (for example, the period T2 or the period T3) may at least partially overlap with the period T2 in which the switch 101 and the switch 103 are turned off. Thus, the feedthrough cancellation circuit 120 may be turned on according to the clock signal CK2 during the period T2 in which the switch 101 and the switch 103 are turned off to perform feedthrough cancellation, and may be turned off according to the clock signal CK2 during the period T1 in which the switch 101 and the switch 103 are turned on to reduce the influence on the buffer circuit 110.

In some embodiments, the clock signal CK1 and/or the clock signal CK2 may have a duty cycle of about 50%, but the present disclosure is not limited thereto. The clock signals CK1 and/or CK2 having duty cycles of various values are all within the contemplated scope of the present disclosure.

FIG. 4 is a schematic diagram of the buffer circuit 110 in FIGS. 1 or 2 according to some embodiments of the present disclosure. As mentioned above, the buffer circuit 110 may be implemented with several source followers. For example, the buffer circuit 110 may include a source follower 410 and a source follower 420. The source follower 410 includes a transistor MN1 and a transistor MP1. A first terminal of the transistor MN1 (e.g., a drain) receives a supply voltage VDD, a second terminal of the transistor MN1 (e.g., a source) and a first terminal of the transistor MP1 (e.g., a source) are coupled to the output node NO1 to generate the output signal VON, and a control terminal of the transistor MN1 (e.g., a gate) and a control terminal of the transistor MP1 (e.g., a gate) are coupled to the input node NI1 to receive the input signal VIN. A second terminal of the transistor MP1 (e.g., a drain) is coupled to ground. With the above arrangement, the source follower 410 may generate the output signal VON according to the input signal VIN.

Similarly, the source follower 420 includes a transistor MN2 and a transistor MP2. A first terminal of the transistor MN2 receives the supply voltage VDD, a second terminal of the transistor MN2 and a first terminal of the transistor MP2 are coupled to the output node NO2 to generate the output signal VOP, and a control terminal of the transistor MN2 and a control terminal of the transistor MP2 are coupled to the input node NI2 to receive an input signal VIP. A second terminal of the transistor MP2 is coupled to ground. With the above arrangement, the source follower 420 may generate the output signal VOP according to the input signal VIP.

When the switch 101 in FIG. 1 is turned off, the input signal VIN may be coupled to the output node NO1 via a parasitic capacitance of the switch 101, a parasitic capacitance of the transistor MN1 (for example, a gate-source capacitance), and a parasitic capacitance of the transistor MP1 (for example, a gate-source capacitance). Therefore, when the switch 101 is turned off, the switch SW2 in the path 124 may be turned on accordingly to connect the input node NI2 to the output node NO1, in order to reduce the influence of signal feedthrough. Similarly, when the switch 103 in FIG. 1 is turned off, the input signal VIP may be coupled to the output node NO2 via a parasitic capacitance of the switch 103, a parasitic capacitance of the transistor MN2 (for example, a gate-source capacitance), and a parasitic capacitance of the transistor MP2 (for example, a gate-source capacitance). Therefore, when the switch 103 is turned off, the switch SW1 in the path 122 may be turned on accordingly to connect the input node NI1 to the output node NO2, in order to reduce the influence of the above signal feedthrough.

The arrangements of the buffer circuit 110 shown in FIG. 4 are given for illustrative purposes, and the present disclosure is not limited thereto. In other embodiments, other circuits may be added to the buffer circuit 110 in FIG. 4 according to actual application requirements, for example, it may include, but is not limited to, an AC coupling circuit and a DC bias circuit. Therefore, various types of the buffer circuit 110 are all within the contemplated scope of the present disclosure.

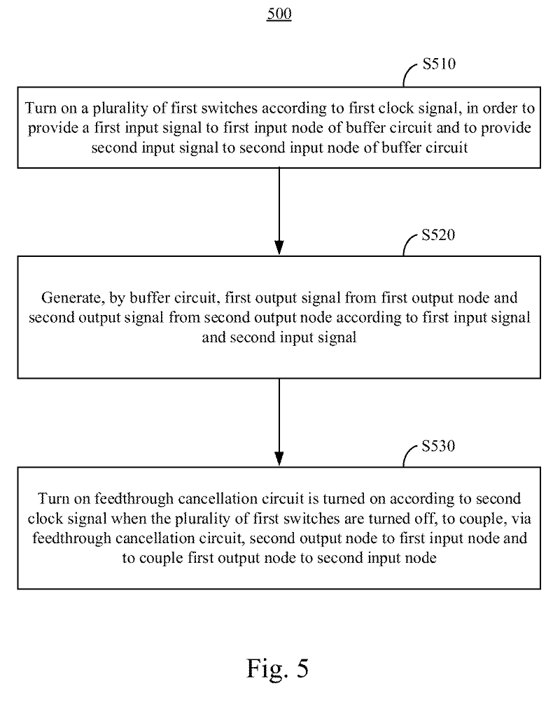

FIG. 5 is a flow chart of a buffer output method 500 according to some embodiments of the present disclosure. In different embodiments, the buffer output method 500 may be performed by either the buffer output device 100 in FIG. 1 or the buffer output device 200 in FIG. 2, but the present disclosure is not limited thereto.

In operation S510, a plurality of first switches are turned on according to a first clock signal, in order to provide a first input signal to a first input node of the buffer circuit and to provide a second input signal to a second input node of the buffer circuit. In operation S520, the buffer circuit generates a first output signal from a first output node and a second output signal from a second output node according to the first input signal and the second input. In operation S530, when the plurality of first switches are turned off, the feedthrough cancellation circuit is turned on according to a second clock signal, to couple, via the feedthrough cancellation circuit, the second output node to the first input node and to couple the first output node to the second input node.

The related operations of the buffer output method 500 may refer to the descriptions of the aforementioned embodiments and therefore will not be repeated here. Operations in the buffer output method 500 include exemplary operations, but the operations in the buffer output method 500 are not necessarily performed in the order described above. Operations in the buffer output method 500 may be added, replaced, changed order, and/or eliminated, or one or more operations in the buffer output method 500 may be executed simultaneously or partially simultaneously as appropriate, in accordance with the spirit and scope of various embodiments of the present disclosure.

As described above, the buffer output device and the buffer output method provided by some embodiments of the present disclosure may use a feedthrough cancellation circuit to reduce the influence of parasitic elements and, through an additional switching mechanism, avoid the feedthrough cancellation circuit affecting the main operation of the buffer circuit.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically include transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely some embodiments of the present disclosure, without any intention to limit the scope of the present disclosure thereto. Various equivalent changes, alterations, or modifications according to the claims of present disclosure are all consequently viewed as being embraced by the scope of the present disclosure.

What is claimed is:

1. A buffer output device, comprising:
a buffer circuit;
a plurality of first switches configured to be turned on according to a first clock signal to provide a first input signal to a first input node of the buffer circuit and to provide a second input signal to a second input node of the buffer circuit,
wherein the buffer circuit is configured to generate a first output signal from a first output node according to the first input signal and to generate a second output signal from a second output node according to the second input signal; and
a feedthrough cancellation circuit configured to be turned on according to a second clock signal when the plurality of first switches are turned off, to couple the second output node to the first input node and to couple the first output node to the second input node.

2. The buffer output device of claim 1, wherein the feedthrough cancellation circuit is configured not to be turned on according to the second clock signal when the plurality of first switches are turned on, in order to disconnect the second output node from the first input node and disconnect the first output node from the second input node.

3. The buffer output device of claim 1, wherein the feedthrough cancellation circuit comprises:
a capacitor coupled to the second output node; and
a second switch coupled between the first input node and the capacitor, and configured to be turned on according to the second clock signal, to couple the first input node to the second output node via the capacitor.

4. The buffer output device of claim 1, wherein the feedthrough cancellation circuit comprises:
a capacitor coupled to the first input node; and
a second switch coupled between the second output node and the capacitor, and configured to be turned on according to the second clock signal, to couple the second output node to the first input node via the capacitor.

5. The buffer output device of claim 1, wherein the buffer circuit comprises:
a first source follower configured to generate the first output signal according to the first input signal; and
a second source follower configured to generate the second output signal according to the second input signal.

6. The buffer output device of claim 1, wherein a period in which the feedthrough cancellation circuit is turned on at least partially overlaps with a period in which the first switches are turned off.

7. The buffer output device of claim 1, wherein the first clock signal and the second clock signal have opposite phases.

8. The buffer output device of claim 1, wherein the first clock signal and the second clock signal are non-overlapping clock signals.

9. A buffer output method, comprising:
turning on a plurality of first switches according to a first clock signal, to provide a first input signal to a first input node of a buffer circuit and to provide a second input signal to a second input node of the buffer circuit;
generating, by the buffer circuit, a first output signal from a first output node and a second output signal from a second output node according to the first input signal and the second input signal; and
turning on a feedthrough cancellation circuit according to a second clock signal when the plurality of first switches are turned off, in order to couple, via the feedthrough cancellation circuit, the second output node to the first input node and to couple the first output node to the second input node.

10. The buffer output method of claim 9, further comprising:
not turning on the feedthrough cancellation circuit according to the second clock signal when the plurality of first switches are turned on, to disconnect the second output node from the first input node and to disconnect the first output node from the second input node.

11. The buffer output method of claim 9, wherein turning on the feedthrough cancellation circuit according to the second clock signal when the plurality of first switches are turned off, to couple, via the feedthrough cancellation circuit, the second output node to the first input node and to couple the first output node to the second input node comprises:
turning on a second switch in the feedthrough cancellation circuit according to the second clock signal, to couple the first input node to the second output node via the second switch and a capacitor in the feedthrough cancellation circuit,
wherein the second switch is coupled between the first input node and the capacitor.

12. The buffer output method of claim 9, wherein turning on the feedthrough cancellation circuit according to the second clock signal when the plurality of first switches are turned off, to couple, via the feedthrough cancellation circuit, the second output node to the first input node and to couple the first output node to the second input node comprises:
turning on a second switch in the feedthrough cancellation circuit according to the second clock signal, to couple the second output node to the first input node via the second switch and a capacitor in the feedthrough cancellation circuit,
wherein the second switch is coupled between the second output node and the capacitor.

13. The buffer output method of claim 9, wherein a period in which the feedthrough cancellation circuit is turned off at least partially overlaps with a period in which the first switches are turned on.

14. The buffer output method of claim 9, wherein the first clock signal and the second clock signal have opposite phases.

15. The buffer output method of claim 9, wherein the first clock signal and the second clock signal are non-overlapping clock signals.
